(19) United States
(12) Patent Application Publication
(10) Pub. No.: US 2026/0173553 A1
(43) Pub. Date: Jun. 18, 2026

(54) IMAGE SENSORS WITH PIXEL LAYOUTS HAVING MULTI-GATE TRANSFER STRUCTURES

(71) Applicant: OMNIVISION TECHNOLOGIES, INC., Santa Clara, CA (US)

(72) Inventor: Woon II Choi, Sunnyvale, CA (US)

(21) Appl. No.: 18/979,461

(22) Filed: Dec. 12, 2024

(51) Int. Cl. H10F 39/00

(52) U.S. Cl. CPC H10F 39/80373

(57) ABSTRACT

Image sensors with pixel layouts having multi-gate transfer structures are disclosed herein. In one embodiment, a pixel arrangement includes a transfer center gate (TCG) transistor, a plurality of pixels, a floating diffusion, and a source follower transistor. The plurality of pixels can be arranged to surround the TCG transistor. Each pixel of the plurality of pixels can include a photosensor and a transfer transistor having a transfer gate positioned between the photosensor and the TCG transistor. The floating diffusion can be disposed at a location proximate the source follower transistor. The floating diffusion can be coupled to the source follower transistor via a metal interconnect having a length corresponding to a minimum design rule. The pixel arrangement can lack junctions positioned between (a) the TCG transistor and (b) one or more of the transfer transistors.

### TECHNICAL FIELD

This disclosure relates generally to image sensors, and in particular but not exclusively, to complementary metal oxide semiconductor (CMOS) image sensors.

### BACKGROUND

Image sensors have become ubiquitous and are now widely used in digital cameras, cellular phones, security cameras, as well as medical, automobile, and other applications. As image sensors are integrated into a broader range of electronic devices, it is desirable to enhance their functionality, performance metrics, and the like in as many ways as possible (e.g., resolution, power consumption, dynamic range, etc.) through both device architecture design as well as image acquisition processing.

A typical image sensor operates in response to image light from an external scene being incident upon the image sensor. The image sensor includes an array of pixels having photosensitive elements (e.g., photodiodes) that absorb a portion of the incident image light and generate image charge upon absorption of the image light. The image charge photogenerated by the pixels may be measured as analog output image signals on column bitlines that vary as a function of the incident image light. In other words, the amount of image charge generated is proportional to the intensity of the image light, which is read out as analog image signals from the column bitlines and converted to digital values to provide information that is representative of the external scene.

### BRIEF DESCRIPTION OF THE DRAWINGS

Non-limiting and non-exhaustive embodiments of the present technology are described below with reference to the following figures, in which like or similar reference numbers are used to refer to like or similar components throughout unless otherwise specified.

FIG. 1 is a partially schematic diagram of an imaging system including a pixel array, each configured in accordance with various embodiments of the present technology.

FIG. 2 is a partially schematic diagram illustrating a layout of a pixel arrangement configured in accordance with various embodiments of the present technology.

FIG. 3 is a partially schematic diagram illustrating metal interconnects of the pixel arrangement of FIG. 2.

FIG. 4 is a simplified partially schematic diagram illustrating various cross-sectional planes through the pixel arrangement of FIG. 2.

FIGS. 5A-5D are partially schematic diagrams illustrating various cross-sections of the pixel arrangement of FIG. 2.

FIG. 6 is a partially schematic diagram illustrating various image charge transfer paths along the pixel arrangement of FIG. 2.

FIG. 7 is a partially schematic diagram illustrating a plurality of microlenses disposed over the pixel arrangement of FIG. 2 in accordance with various embodiments of the present technology.

FIG. 8 is a partially schematic diagram illustrating a single microlens disposed over the pixel arrangement of FIG. 2 in accordance with various embodiments of the present technology.

Skilled artisans will appreciate that elements in the figures are illustrated for simplicity and clarity and are not necessarily drawn to scale. For example, the dimensions of some of the elements in the figures may be exaggerated relative to other elements to aid in understanding of various aspects of the present technology. In addition, common but well-understood elements or methods that are useful or necessary in a commercially feasible embodiment are often not depicted in the figures, or described in detail below, to avoid unnecessarily obscuring the description of various aspects of the present technology.

### DETAILED DESCRIPTION

The present disclosure relates to image sensors with multi-gate transfer structures, and to associated systems, devices, and methods. For example, several embodiments of the present technology are directed to image sensors that can be operated to provide various conversion gains with relatively low noise. Such image sensors can include a plurality of pixels, with one or more of the pixels sharing a multi-gate transfer structure that can reduce a floating diffusion junction size and/or a floating diffusion metal interconnect length. In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element's or feature's relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

It will be understood that, although the terms first, second, third, etc., may be used in the disclosure and claims to describe various elements, these elements should not be limited by these terms and should not be used to determine the process sequence or formation order of associated elements. Unless otherwise indicated, these terms are merely used to distinguish one element from another element. Thus, a first element discussed below could be termed a second element without departing from the teachings of the disclosed embodiments.

It is appreciated that the term “photosensor” or “photodiode” may correspond to a doped region disposed within the semiconductor material configured to photogenerate image charge(s) (e.g., one or more electrons or holes) in response to incident light. For example, photodiode may correspond to an n-doped region disposed within a p-type semiconductor material or an n-doped region surrounded by a p-type well disposed within the semiconductor material.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

### A. Overview

Image sensors having pixels arrangements with multi-gate transfer structures (and associated systems, devices, and methods) are disclosed. For example, several embodiments of the present technology are directed to various imaging systems with pixel arrangements that can be operated in various conversion gain modes with relatively low noise.

Although normal image sensors offer great image capturing capabilities, one of the limitations with normal image sensors is that normal image sensors do not provide sufficiently low noise binning capabilities that may be useful in a variety of applications, particularly in low light settings. For example, many image sensors utilize a 2×2 shared pixel architecture with a lateral overflow integration capacitors (LOFICs). Such image sensors have difficulty implementing 4-cell (4C) binning while achieving high conversion gain with low noise, especially in low light conditions. One reason for this is that the 4C LOFIC arrangements utilized in these image sensors use large floating diffusion junctions. Another reason for this is that the 4C LOFIC arrangements utilized in these image sensors require long metal interconnects to couple floating diffusions to corresponding source follower transistors for reading out image charge. The large floating diffusion junctions and long metal interconnects cause high floating diffusion capacitance, which can decrease conversion gain and increase readout noise. As a result, performance of such image sensors in low light settings suffers. Attempts to provide image sensors with low noise binning capabilities have, thus far, resulted in compromised solutions that provide poor quality image captures.

It is appreciated that circuit designs configured in accordance with various embodiments of the present technology address at least some of the issues discussed above. For example, a pixel arrangement disclosed herein can include a transfer center gate (TCG) transistor and an outgoing gate (OG) transistor that are shared between multiple pixels or sub-pixels, a source follower transistor, and a floating diffusion coupled between the TCG or OG transistor and the source follower transistor. In some embodiments, the floating diffusion is coupled to the source follower transistor via a metal interconnect having a length corresponding to a minimum design rule. In some embodiments, the TCG transistor is coupled to each of the pixels or sub-pixels, the OG transistor, and/or a reset transistor without metal interconnects or junctions.

Thus, as will be shown and described in the various examples below, a pixel arrangement configured in accordance with some embodiments of the present technology can include four pixels, a transfer center gate (TCG) transistor, a floating diffusion, and a source follower transistor. Each of the four pixels can include a photosensor disposed in a semiconductor material layer, and a transfer transistor disposed on the semiconductor material layer and coupled to the photosensor. The TCG transistor can be disposed on the semiconductor material layer between the four pixels. In some embodiments, the pixel arrangement can lack junctions between the transfer transistors of the pixels and the TCG transistor. The source follower transistor can be disposed on the semiconductor material layer. The floating diffusion can be disposed in the semiconductor material layer between two adjacent ones of the pixels and proximate the source follower transistor. The floating diffusion can therefore be coupled to a source follower gate of the source follower transistor using a short metal interconnect, where a distance between the floating diffusion and the source follower gate can be a minimum distance allowable by the process design rule for a given technology node. In some embodiments, the pixel arrangement further includes an outgoing gate (OG) transistor selectively coupling the TCG transistor to the floating diffusion. The OG transistor can be used to adjust capacitance of the floating diffusion and thereby modulate conversion gain. Additionally, or alternatively, use of an OG transistor can enable use of a small floating diffusion junction. One or more of the pixels can additionally include a lateral overflow integration capacitor (LOFIC), an overflow gate (OFG) transistor, and a lateral flow gate (LFG) transistor. The pixel arrangement can further include one or more dual floating diffusion (DFD) transistors, each coupled between two adjacent pixels. Each of the transistors can be usable to modulate a conversion gain of the pixel circuit.

The present technology is expected to offer several advantages. For example, pixel arrangements of the present technology can utilize small floating diffusion junctions with short metal interconnects coupling each of the floating diffusions to a source follower gate of a corresponding source follower transistors. As a result, pixel arrangements of the present technology can exhibit lower effective floating diffusion capacitance, enabling higher conversion gain for signal readout, especially in low light settings, in comparison to other arrangements utilized in other image sensors. In addition, the present technology is expected to provide controlled transfer of image charge from pixels to readout circuitry, which is expected to (a) facilitate selecting a suitable conversion gain mode from a group of possible conversion gain modes, (b) facilitate binned and non-binned readouts, and (c) enable high dynamic range (HDR). The TCG and OG transistors, in particular, can facilitate such transfer of image charges with sequential activation and deactivation for achieving very high conversion gain. Additionally, or alternatively, for low conversion gain, the TCG and OG transistors can be simultaneously activated (e.g., via biasing control) to increase full well capacity (FWC) of a floating diffusion. Furthermore, pixel arrangements of the present technology can be used in 2×2 global shutter implementations without storage voltage budget loss. Moreover, pixel arrangements of the present technology can be implemented in LOFIC-based pixels. As still another advantage, pixel arrangements of the present technology can be used in a wide range of applications, including mobile applications, automotive applications, and security applications, among other applications.

### B. Selected Embodiments of Imaging Sensors With Multi-Gate Transfer Structures, and Associated Systems, Devices, and Methods

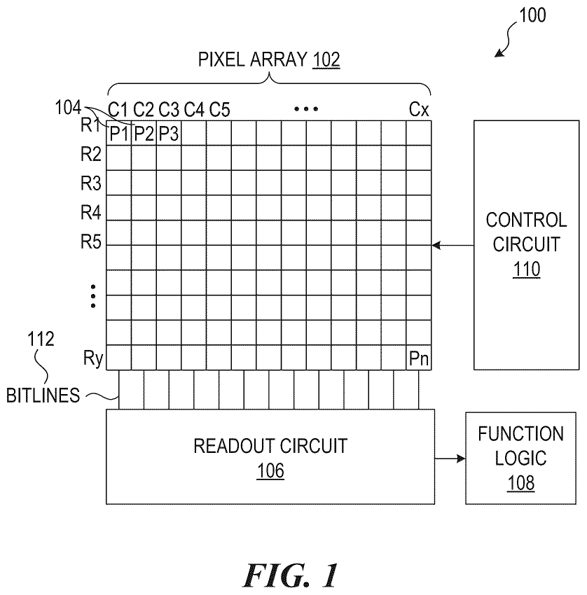

FIG. 1 is a partially schematic diagram of an imaging system 100 configured in accordance with various embodiments of the present technology. The imaging system 100 includes a pixel array 102, bitlines 112, a control circuit 110, a readout circuit 106, and function logic 108. In one example, pixel array 102 is a two-dimensional (2D) array including a plurality of pixel circuits 104 (e.g., P1, P2, P3, . . . ., Pn) that are arranged into rows (e.g., R1 to Ry) and columns (e.g., C1 to Cx) to acquire image data of a person, place, object, etc., which can then be used to render an image of a person, place, object, etc. In various examples, the pixel circuits P1, P2, P3, . . . , Pn include photosensors (e.g., photodiodes) that are configured to provide image data.

In various examples, the readout circuit 106 may be configured to read out the image data through the column bitlines 112. As will be discussed, in the various examples, readout circuit 106 may include an analog-to-digital converter (ADC) (not shown) in accordance with the teachings of the present disclosure. In the example, digital image data values generated by the analog to digital converters in readout circuit 106 may then be received by function logic 108. Function logic 108 may simply store the digital image data or even manipulate the digital image data by applying post image effects (e.g., crop, rotate, remove red eye, adjust brightness, adjust contrast, or otherwise).

In one example, control circuit 110 is coupled to pixel array 102 to control operation of the plurality of photosensors in pixel array 102. For example, control circuit 110 may generate a rolling shutter or a shutter signal for controlling image acquisition. In other examples, image acquisition is synchronized with lighting effects such as a flash.

In one example, imaging system 100 may be included in a digital camera, cell phone, laptop computer, an endoscope, a security camera, or an imaging device for automobile, and/or the like. Additionally, imaging system 100 may be coupled to other pieces of hardware such as a processor (general purpose or otherwise), memory elements, output (USB port, wireless transmitter, HDMI port, etc.), lighting/flash, electrical input (keyboard, touch display, track pad, mouse, microphone, etc.), and/or display. Other pieces of hardware may deliver instructions to imaging system 100, extract image data from imaging system 100, or manipulate image data supplied by imaging system 100.

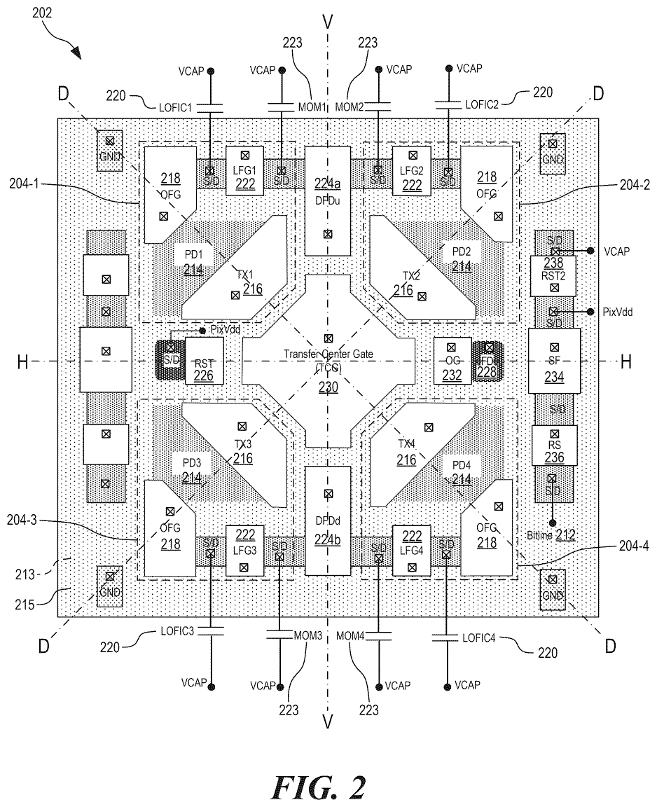

FIG. 2 is a partially schematic diagram illustrating a layout of a pixel arrangement 202 configured in accordance with various embodiments of the present technology. It is appreciated that the pixel arrangement 202 of FIG. 2 may be an example of the pixel array 102 (or a portion thereof) included in the imaging system 100 of FIG. 1, and that similarly named and numbered elements described above are coupled and function similarly below.

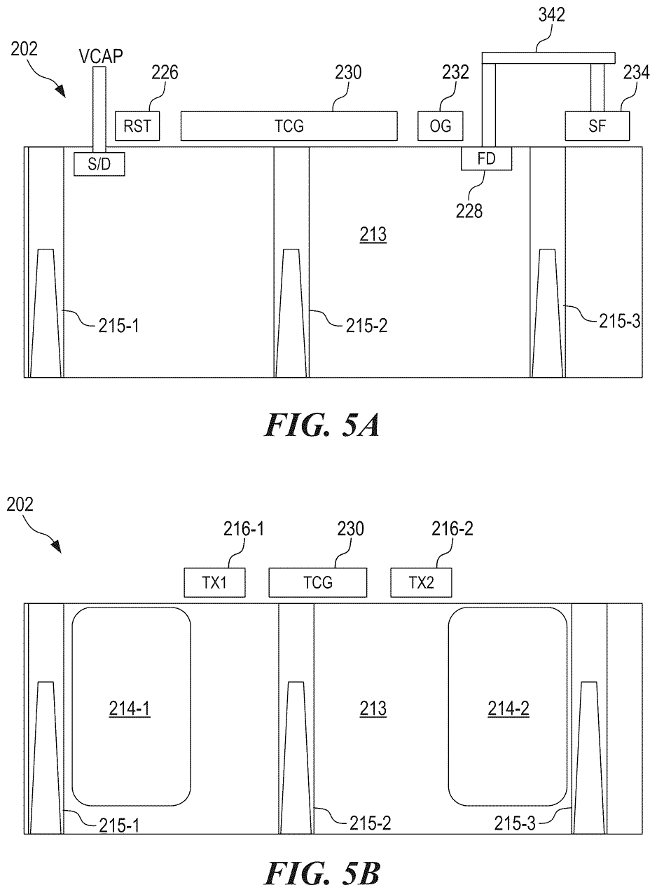

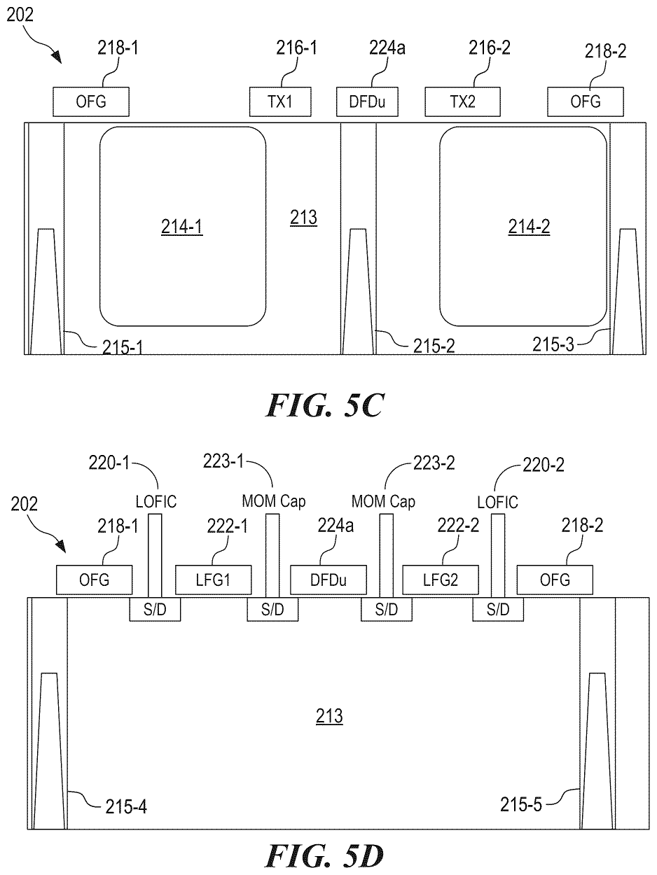

In the illustrated embodiment, the pixel arrangement 202 includes a semiconductor material layer 213 (e.g., silicon) and a plurality of pixel circuits 204 (individually labeled 204-1, 204-2, 204-3, 204-4 in FIG. 2, also referred to as “the pixels 204”). It is appreciated that each pixel circuit 204 (“pixel 204”) may be an example of one of the pixel circuits 104 of FIG. 1, or of other pixel circuits configured in accordance with the present technology. In the illustrated embodiment, the plurality of pixel circuits 204 is grouped into a unit pixel and the plurality of pixels 204 are arranged in a 2×2 array or configuration. In some embodiments, the pixel arrangement 202 further includes one or more isolation regions 215 (e.g., shallow trench isolation (STI) regions, deep trench isolation (DTI) regions) disposed or embedded in the semiconductor material layer 213, and disposed between individual ones of the pixels 204 and/or elsewhere. The isolation regions 215 are illustrated in and discussed in further detail below with reference to FIGS. 5A-5D. In some embodiments, the pixel arrangement 202 does not include isolation structures. As shown in FIG. 2, each pixel 204 can include a photosensor 214 (e.g., a photodiode) and a transfer transistor 216. In these and other embodiments, each pixel 204 can further include a lateral overflow integration capacitor (LOFIC) 220, an overflow gate (OFG) transistor 218, and a lateral flow gate (LFG) transistor 222. Alternatively, the LOFIC 220, the OFG transistor 218, and/or the LFG transistor 222 can be omitted from one or more of the pixels 204.

In some embodiments, the semiconductor material layer 213 includes or is otherwise formed of silicon, a silicon germanium alloy, germanium, a silicon carbide alloy, an indium gallium arsenide alloy, any other alloys formed of III-V group compounds, combinations thereof, one or more epitaxial layers of the aforementioned materials, or a bulk substrate thereof. More specifically, the semiconductor material layer 213 may correspond to any semiconductor material or combination of materials that may be doped or otherwise configured to facilitate the formation of an integrated circuit (e.g., individual circuitry components such as source/drain regions of transistors, memory elements, photosensors, and/or the like). In some embodiments, the semiconductor material layer 213 corresponds to an epitaxial layer (e.g., P-type silicon layer or N-type silicon layer). In such embodiments, photosensors (e.g., first photodiode PD1, second photodiode PD2, third photodiode PD3, and fourth photodiode PD4 illustrated in FIG. 2 or other photodiodes included in the pixel cell array (e.g., the pixel array 102 illustrated in FIG. 1) may be formed in the epitaxial layer corresponding to the semiconductor material layer 213.

The photosensor 214 of each pixel 204 can be disposed in the semiconductor material layer 213 and configured to generate image charge in response to incident light. The transfer transistor 216, the OFG transistor 218, and the LFG transistor 222 included in each pixel 204 can be formed or otherwise disposed on the semiconductor material layer 213. In the illustrated embodiment, the transfer transistor 216 of each pixel 204 is disposed closest to the center of the 2×2 configuration, and the OFG transistor 218 is disposed farthest from the center of the 2×2 configuration. The LFG transistor 222 can be disposed adjacent to the OFG transistor 218 with a source/drain region therebetween. In particular, the OFG transistor 218 and the LFG transistor 222 can be disposed at a periphery of the plurality of pixels 204 (e.g., four pixels). The LOFIC 220 of each pixel 204 can be coupled between (i) the source/drain region between the LFG transistor 222 and the OFG transistor 218 and (ii) a voltage supply VCAP. In some embodiments, the LOFIC 220 comprises a 3D or trenched metal-insulator-metal (MIM) capacitor. In some embodiments, the LOFIC 220 is implemented with a metal-insulator-metal capacitor including an insulating material with high dielectric constant or high-k insulating material disposed between a first metal electrode and a second metal electrode. In various examples, the insulating material disposed between the first metal electrode and the second metal electrode of the LOFIC 220 may be formed of a single layer of high-k material or a multiple layer stack of high-k material. The exact composition and thickness of the high-k material may depend on the desired LOFIC capacitance. In the various examples, the high-k material may include one of aluminum oxide (Al₂O₃), Zirconium dioxide (ZrO₂), Hafnium oxide (HfO), or a combination thereof. In one example, it is appreciated that the first metal electrode of the LOFIC 220 may be referred to as a capacitor top metal (CTM) and the second metal electrode of the LOFIC 220 may be referred to as a capacitor bottom metal (CBM).

The LFG transistor 222 of each pixel 204 can selectively couple the corresponding LOFIC 220 to a dual floating diffusion (DFD) transistor disposed on the semiconductor material layer 213 and between two of the pixels 204. For example, in the illustrated embodiment, the LFG transistors 222 of the first pixel 204-1 and the second pixel 204-2 selectively couple the corresponding LOFICs 220 to a first DFD transistor 224a, and the LFG transistors 222 of the third pixel 204-3 and the fourth pixel 204-4 selectively couple the corresponding LOFICs 220 to a second DFD transistor 224b, thereby providing LOFIC conversion gain readout paths. In some embodiments, each pixel 204 further includes a metal-oxide-metal (MOM) capacitor 223 coupled between (i) a source/drain region between the corresponding LFG transistor 222 and the DFD transistor 224a or 224b and (ii) the supply voltage VCAP for low conversion gain readout.

As shown, the pixel arrangement 202 can further include a transfer center gate (TCG) transistor 230, an outgoing gate (OG) transistor 232, a reset (RST) transistor 226, and a floating diffusion (FD) 228. The TCG transistor 230, the OG transistor 232, and the RST transistor 226 can be disposed on the semiconductor material layer 213, and the FD 228 can be disposed in the semiconductor material layer 213, for example via ion implantation. In particular, the TCG transistor 230 can be disposed at the center of the 2×2 configuration (e.g., between the first pixel 204-1 and the fourth pixel 204-4, and between the second pixel 204-2 and the third pixel 204-3). Transfer transistors 216 of the pixels 204 can be disposed to surround the TCG transistor 230. Each of the transfer transistors 216 can selectively couple the corresponding photosensor 214 to the TCG transistor 230. In turn, the TCG transistor 230 can selectively couple the transfer transistor 216 of each of the plurality of pixels 204 (e.g. four pixels) to (a) the OG transistor 232 and (b) the RST transistor 226.

Notably, the TCG transistor 230 can have a larger gate area than any of the other transistors included in the pixel arrangement 202, as shown in FIG. 2. In some embodiments, the TCG transistor 230 is configured to comprise a MOSCAP configured to hold image charge from the photosensors 214 of the pixels 204 and modulate a conversion gain level of signal readout for the pixel arrangement 202. As shown in FIG. 2, the pixel arrangement 202 can lack or omit junctions (i) between (e.g., electrically positioned between) one or more of the transistor transistors 216 and the TCG transistor 230, (ii) between (e.g., electrically positioned between) the RST transistor 226 and the TCG transistor 230, and/or (iii) between (e.g., electrically positioned between) the OG transistor 232 and the TCG transistor 230.

The OG transistor 232 can be disposed proximate or adjacent to the TCG transistor 230 and between the second pixel 204-2 and the fourth pixel 204-4. An OG gate of the OG transistor 232 can be disposed in a region between the transfer gate of the transfer transistor 216 associated with the second pixel 204-2 and the transfer gate of the transfer transistor 216 associated with the fourth pixel 204-4. The OG transistor 232 can selectively couple the TCG transistor 230 to the FD 228. The FD 228 can be disposed proximate or adjacent to the OG transistor 232 and/or between the second pixel 204-2 and the fourth pixel 204-4. As discussed in greater detail below, such positioning of the FD 228 can be close to (e.g., at a location proximate) a source follower transistor 234 of the pixel arrangement 202, allowing use of a short (e.g., shortest possible) metal interconnect between the FD 228 and the source follower transistor 234. Additionally, or alternatively, use of the OG transistor 232 at a position proximate the FD 228 and between (e.g., electrically positioned between) the TCG transistor 230 and the FD 228 facilitates use of a small (e.g., minimally sized) floating diffusion junction. Furthermore, the lack of junctions between (i) the TCG transistor 230 and (ii) the transfer transistor 216, the RST transistor 226, and/or the OG transistor 232, can limit the floating diffusion junction size to the size of the junction corresponding to the FD 228. As discussed in greater detail below, use of a short metal interconnect and a small floating diffusion junction is expected to (a) reduce or minimize floating diffusion capacitance and (b) decrease or minimize readout noise, thereby resulting in improved performance in low light settings and/or binning applications in comparison to other pixel arrangements.

In some embodiments, the RST transistor 226 is coupled to the floating diffusion 228 through the TCG transistor 230. The TCG transistor 230 can be disposed between the RST transistor 226 and the floating diffusion 228 such that (i) charge transfer paths between the photosensors 214 and the floating diffusion 228 and (ii) anti-blooming paths for the photosensors 214 can be separated. In various examples, the gate terminal of the TCG transistor 230 is disposed to separate the gate terminal of the RST transistor 226 from the floating diffusion 228.

Image charges can be transferred from each photosensor 214 to the floating diffusion 228 through the TCG transistor 230 and the OG transistor 232. Image charges photogenerated by individual photosensors 214 during charge transfer and/or readout operations can be drained to voltage source supplying voltage PIXVDD through an anti-blooming path formed by the TCG transistor 230 and the RST transistor 226. Moreover, excess image charges photogenerated by photosensors 214 included in the pixel arrangement 202 can be configured to overflow to corresponding LOFICs 220 and/or MOM capacitor 223 through overflow paths formed by the corresponding OFG transistor 218 coupled to the respective photosensor 214 and LFG transistor 222.

With continuing reference to FIG. 2, the RST transistor 226 can be disposed adjacent to the TCG transistor 230 and between the first pixel 204-1 and the third pixel 204-3. Therefore, the OG transistor 232 and the RST transistor 226 can be disposed on opposite sides of the TCG transistor 230. In some embodiments, positions of the gates of the OG transistor 232 and the RST transistor 226 are horizontally aligned. In some embodiments, the RST transistor 226 is coupled to the FD 228 through a channel connection of the TCG transistor 230 and without metal routing or interconnects. The RST transistor 226 can selectively couple the TCG transistor 230 to a supply voltage PIXVDD.

As illustrated in FIG. 2, the four pixels 204 and the TCG transistor 230 can be symmetrical about one or more symmetry lines, such as about a horizontal line H-H (e.g., extending left and right across the figure), about a vertical line V-V (e.g., extending up and down across the figure), and/or about diagonal lines D-D (e.g., extending through the TCG gate of the TCG transistor 230 toward the four corners of the pixel arrangement 202). Additionally, or alternatively, the four pixels 204 and the TCG transistor 230 can also exhibit rotational symmetry about an axis extending through the TCG transistor 230 (e.g., into and through the page) such that the pixels 204 and the TCG transistor 230 can be rotated by 90 degrees or 180 degrees and retain a same or similar general layout to that shown in FIG. 2. The symmetric arrangement of the various transistors described herein and the gates thereof can help mitigate issues that may arise from, among others, non-uniformity of the photosensors 214.

The pixel arrangement 202 can further include shared readout circuity. More specifically, the pixel arrangement 202 can include the source follower (SF) transistor 234, a row select transistor 236, and a second reset transistor 238, each of which can be disposed on the semiconductor material layer 213. As discussed above, The FD 228 can be disposed between the OG transistor 232 and the SF transistor 234. In particular, the FD 228 can be coupled to a gate of the SF transistor 234. The FD 228 and the drain of the reset transistor 226 can be disposed on opposite sides of the gate electrode TCG of the TCG transistor 230. In some embodiments, the FD 228 and the drain of the reset transistor 226 are horizontally aligned, enabling the pixel arrangement 202 to be symmetric about the gate electrode TCG of the TCG transistor 230. The second reset transistor 238 can selectively couple the SF transistor 234 to the supply voltage VCAP. In some embodiments, the second reset transistor 238 can be omitted. In such embodiments, the SF transistor 234 can be coupled to the supply voltage VCAP. The SF transistor 234 is configured to output an analog image charge data signal to a bitline (BL) 212 through the row select transistor 236. The analog image charge data signal output onto the column bitline is based at least in part on an amount of image charge at the FD 228.

In some embodiments, ground contacts for the pixel arrangement 202 and/or adjacent pixel arrangements (not illustrated) may be disposed in one or more corner regions of the respective pixel arrangement (e.g., between the gate electrode OFG of the OFG transistor 218 of the second pixel 204-2 and the second reset transistor RST2 238) for grounding the semiconductor material layer 213 while enabling the pixel arrangement 202 to have both vertical and horizontal symmetry.

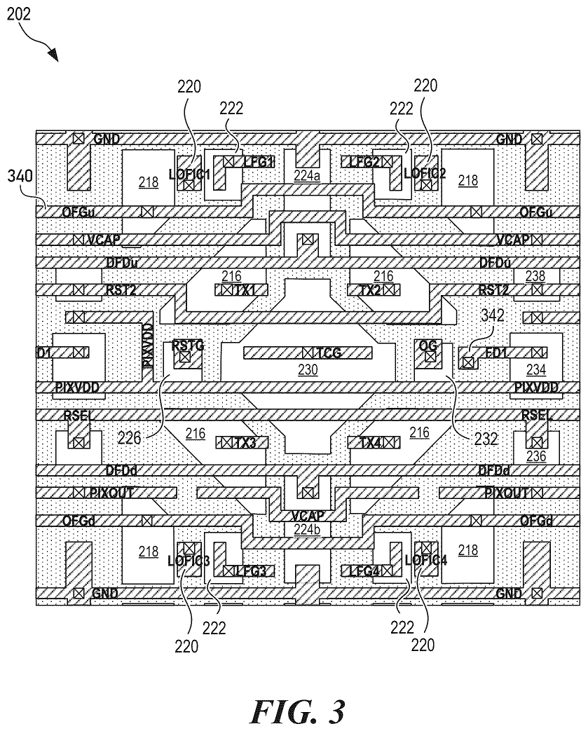

FIG. 3 is a partially schematic diagram illustrating metal interconnects of the pixel arrangement 202. In the illustrated embodiment, the pixel arrangement 202 includes a plurality of metal interconnects 340 that can provide control signals, voltage levels from the voltage supply VCAP, connections to the LOFICs 220, connections between select components of the pixel arrangement 202, etc. For example, referring to FIGS. 2 and 3 together, each transfer transistor 216, each LFG transistor 222, and each DFD transistor 224a, 224b is coupled to receive independent control signals TX1-TX4, LFG1-LFG4, and DFDu and DFDd, respectively, from separate metal interconnects 340. The OFG transistors 218 of the first pixel 204-1 and the second pixel 204-2 can share a control signal OFGu, and the OFG transistors 218 of the third pixel 204-3 and the fourth pixel 204-4 can share a control signal OFGd.

The TCG transistor 230, the OG transistor 232, and the RST transistor 226 are also coupled to receive independent control signals TCG, OG, and RSTG, respectively, from separate metal interconnects 340. In some embodiments, the pixel arrangement 202 lacks junctions (e.g., p-n junctions, high-conductivity doped silicon regions, or source/drain regions) between the TCG transistor 230 and one or more other elements of the pixel arrangement. For example, a drain terminal of the TCG transistor 230 can be coupled (e.g., directly coupled) to drain terminals of one or more of the transfer transistors 216 such that the pixel arrangement 202 lacks a junction between the TCG transistor 230 and one or more transfer transistors 216. As a specific example, the TCG transistor 230 can share a drain terminal with the transfer transistors 216. Additionally, or alternatively, the drain terminal of the TCG transistor 230 can be coupled (e.g., directly coupled) to a source terminal of the RST transistor 226 such that the pixel arrangement 202 lacks a junction between the TCG transistor 230 and the RST transistor 226. As a specific example, the drain terminal of the TCG transistor 230 can be the source terminal of the RST transistor 226. In these and other embodiments, the source terminal of the TCG transistor 230 can be coupled (e.g., directly coupled) to the drain terminal of the OG transistor 232 such that the pixel arrangement 202 lacks a junction between the TCG transistor 230 and the OG transistor 232. As a specific example, the source terminal of the TCG transistor 230 can be the drain terminal of the OG transistor 232. In some embodiments, the pixel arrangement 202 includes one or more buried channel doped regions extending between different transistors through the semiconductor material layer 213. The one or more buried channels can provide sufficient electrical connections between the transistors.

As discussed above, the pixel arrangement 202 illustrated in FIGS. 2 and 3 can provide several advantages over other pixel circuits. For example, in other pixel arrangements that implement 2×2 pixel configurations, floating diffusions (i) are typically positioned at centers of four pixels and (ii) have large junction sizes. The large floating diffusion junction sizes lead to larger amounts of floating diffusion capacitance (e.g., gate overlap capacitance). Furthermore, the central positions of the floating diffusions in these other pixel arrangements are typically remote from locations of corresponding source follower transistors. Therefore, relatively long metal interconnects are typically used to connect the floating diffusions to the source follower transistors. The long metal interconnects contribute to increased metal routing coupling capacitance. In turn, the increased floating diffusion capacitance (e.g., due to the large floating diffusion junction sizes and the long metal interconnects) decreases conversion gain, which can increase readout noise and result in poor performance, especially in low-light conditions.

In contrast, the FD 228 of the pixel arrangement 202 illustrated in FIGS. 2 and 3 (a) is positioned closer to the SF transistor 234 than the center of the four pixels (e.g., where the TCG transistor 230 is positioned), and (b) is coupled to each of the pixels 204 via the TCG transistor 230 and the OG transistor 232, allowing the junction size of the FD 228 to be relatively small. The small floating diffusion junction size can translate to less floating diffusion capacitance (e.g., less gate overlap capacitance). In addition, the position of the FD 228 proximate the SF transistor 234 facilitates use of a relatively short metal interconnect 342 to couple the FD 228 to the SF transistor 234, resulting in less metal routing coupling capacitance. In some embodiments, the length of the metal interconnect 342 corresponds to a minimum design rule for a given technology node. Minimum design refers to the smallest allowable dimensions and spacing for features in a semiconductor device, ensuring functionality while optimizing space and performance. Thus, embodiments of the present technology can utilize floating diffusions with smaller junction sizes and shorter metal interconnects extending between the floating diffusions and corresponding source follower transistors, which is expected to reduce or minimize floating diffusion capacitance and thereby achieve higher conversion gain levels with reduced readout noise. As such, pixel arrangements configured in accordance with the present technology are expected to perform better than other pixel arrangements, especially in low-light conditions and/or in 2×4-cell (4C) binning applications.

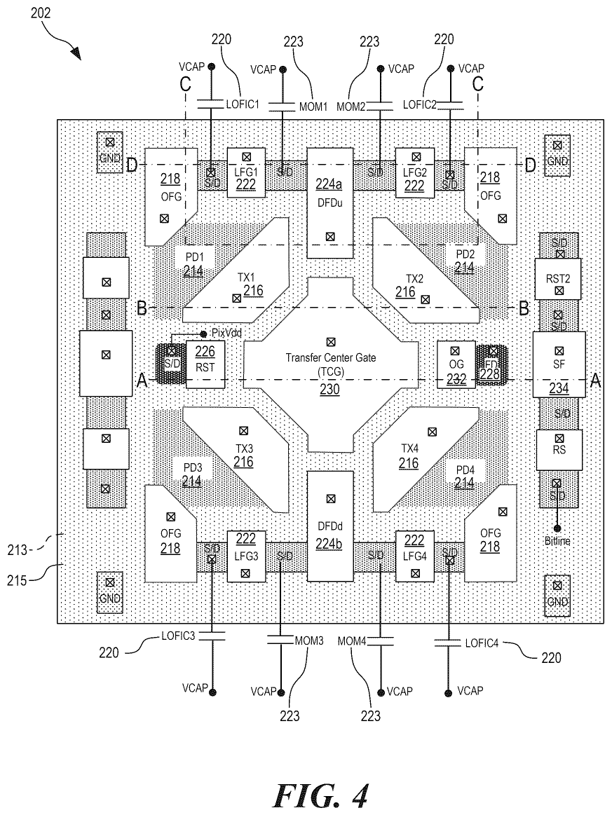

FIG. 4 is a simplified partially schematic diagram illustrating various cross-sectional planes through the pixel arrangement 202 configured in accordance with various embodiments of the present technology. As shown, a first cross-sectional plane A-A extends laterally through the RST transistor 226, the TCG transistor 230, the OG transistor 232, the FD 228, and the SF transistor 234. A second cross-sectional plane B-B extends laterally through (i) the TCG transistor 230, and (ii) the photosensors 214 and the transfer transistors 216 of the first and second pixels 204-1, 204-2. A third cross-sectional plane C-C extends in multiple directions through (i) the DFD transistor 224a, and (ii) the photosensors 214, the transfer transistors 216, and the OFG transistors 218 of the first and second pixels 204-1, 204-2. A fourth cross-sectional plane D-D extends laterally through (i) the DFD transistor 224a, and (ii) the OFG transistors 218 and the LFG transistors 222 of the first and second pixels 204-1, 204-2. As discussed in further detail below, FIGS. 5A-5D illustrate cross-sections of the pixel arrangement 202 taken at the first cross-sectional plane A-A, the second cross-sectional plane B-B, the third cross-sectional plane C-C, and the fourth cross-sectional plane D-D, respectively.

Referring first to FIG. 5A that illustrates a cross-section of the pixel arrangement 202 taken along plane A-A of FIG. 4, the RST transistor 226, the TCG transistor 230, the OG transistor 232, and the SF transistor 234 can be at least partially disposed on the semiconductor material layer 213 (e.g., in a generally linear arrangement). The source/drain (“S/D”) region of the RST transistor 226 can be disposed in the semiconductor material layer 213 and coupled to the voltage supply VCAP. Notably, the pixel arrangement 202 can lack junctions between the TCG transistor 230 and other components of the pixel arrangement 202. For example, as shown in FIG. 5A, the pixel arrangement 202 does not include a junction in the semiconductor material layer 213 between the RST transistor 226 and the TCG transistor 230. Nor does the pixel arrangement 202 include a junction in the semiconductor material layer 213 between the TCG transistor 230 and the OG transistor 232. In accordance with the discussion of FIG. 2 above, the FD 228 is disposed in the semiconductor material layer 213 generally between the OG transistor 232 and the SF transistor 234. For example, the FD 228 can be disposed in the semiconductor material layer 213 between the gate terminal (e.g., OG gate) of the OG transistor 232 and the gate terminal of the SF transistor 234. A short metal interconnect 342 connects the FD 228 to the SF transistor 234 (e.g., to the gate terminal (or source follower gate) of the SF transistor 234).

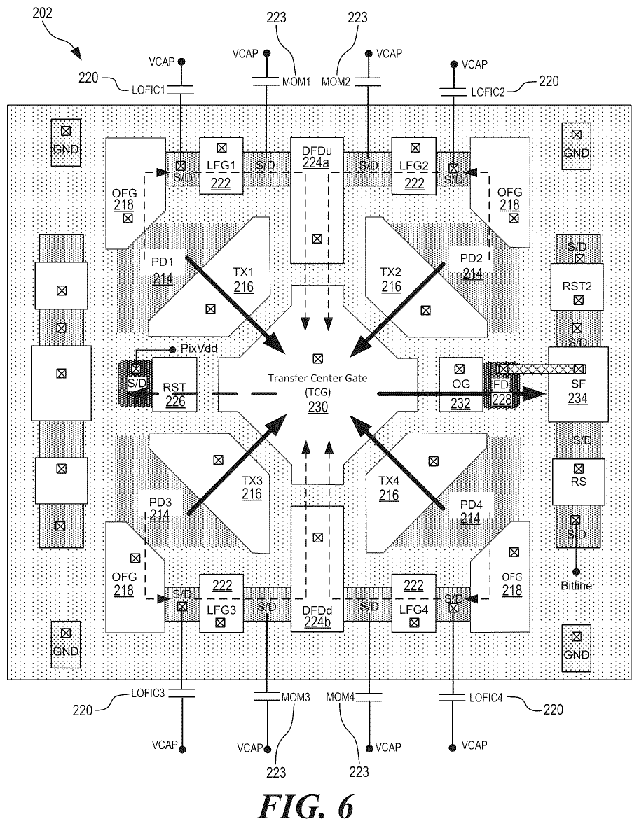

The pixel arrangement further includes a plurality of isolation regions 215 (e.g., shallow trench isolation (STI) regions, deep trench isolation (DTI) regions) embedded in the semiconductor material layer 213. In the illustrated embodiment, a first isolation region 215-1 is disposed on a side of the RST transistor 226 opposite the TCG transistor 230, and can isolate the illustrated pixel arrangement 202 from an adjacent pixel arrangement (not shown). A second isolation region 215-2 can be disposed underneath the gate electrode TCG of TCG transistor 230, and can isolate the RST transistor 226 from the OG transistor 232, the FD 228, and the SF transistor 234. As discussed in further detail below with reference to FIG. 6, isolating the two opposite sides of the TCG transistor 230 shown in FIG. 5A can enable separate image flow paths for readout and anti-blooming. A third isolation region 215-3 is shown disposed between the FD 228 and the SF transistor 234, and can isolate the FD 228 from the SF transistor 234 (e.g., such that image charge flows between the FD 228 and the SF transistor 234 via the metal interconnect 342). Each of the first isolation region 215-1, the second isolation region 215-2, and the third isolation region 215-3 may be interconnected and part of an isolation grid. Each of the first isolation region 215-1, the second isolation region 215-2, and the third isolation region 215-3 may be disposed in or otherwise surrounded by a well or doped region formed in the semiconductor material layer 213 and extending between front and back surfaces of the semiconductor material layer 213.

Referring next to FIG. 5B that illustrates a cross-section of the pixel arrangement taken along the plane B-B of FIG. 4, the first pixel's photosensor 214-1 and the second pixel's photosensor 214-2 are shown disposed and/or embedded in the semiconductor material layer 213. The first pixel's transfer transistor 216-1 and the second pixel's transfer transistor 516-2 can be at least partially disposed on the semiconductor material layer 213 on opposite sides of the TCG transistor 230. In particular, the transfer transistor 216-1 is disposed generally between the photosensor 214-1 and the TCG transistor 230, and the transfer transistor 216-2 is disposed generally between the photosensor 214-2 and the TCG transistor 230. Consistent with the discussion above, the pixel arrangement 202 can lack junctions between the TCG transistor 230 and other components of the pixel arrangement 202. For example, as shown in FIG. 5B, the pixel arrangement 202 does not include a junction in the semiconductor material layer 213 between the transfer transistor 216-1 and the TCG transistor 230. Nor does the pixel arrangement 202 include a junction in the semiconductor material layer 213 between the TCG transistor 230 and the transfer transistor 216-2.

Furthermore, the first isolation region 215-1 can be disposed on the opposite side of the photosensor 214-1 as the transfer transistor 216-1, and can isolate the illustrated pixel arrangement 202 from an adjacent pixel arrangement (not shown). The second isolation region 215-2 can be disposed underneath the gate electrode TCG of the TCG transistor 230, and may be disposed into a doped well region and can isolate the transfer transistor 216-1 from the transfer transistor 216-2. The third isolation region 215-3 can be disposed on a side of the photosensor 214-2 opposite the transfer transistor 216-2, and can isolate the photosensor 214-2 from shared readout circuity (e.g., including the SF transistor 234) and/or an adjacent pixel arrangement (not shown).

As shown in FIG. 5B, gate electrode TCG of TCG transistor 230, transfer gate TX1 of transfer transistor 216-1, and transfer gate TX2 of transfer transistor 216-2 can be disposed on the semiconductor material layer 213. In some embodiments, an insulation layer (e.g., oxide-based material; not shown) functioning as a gate oxide can be disposed between gate electrode TCG of TCG transistor 230, transfer gate TX1 of transfer transistor 216-1, transfer gate TX2 of transfer transistor 216-2, and the semiconductor material layer 213.

Transfer gate TX1 of transfer transistor 216-1 can be disposed proximate to the photosensor 214-1 and can selectively couple the photosensor 214-1 to the floating diffusion 228. Transfer gate of transfer transistor 216-2 can be disposed proximate to the photosensor 214-2 and can selectively couple the photosensor 214-2 to the floating diffusion 228. Gate electrode TCG of TCG transistor 230, transfer gate TX1 of transfer transistor 216-1, and transfer gate TX2 of transfer transistor 216-2 may be further isolated from one another by a dielectric material (e.g., oxide, nitride, and/or the like). In some embodiments, each of gate electrode TCG of TCG transistor 230, transfer gate TX1 of transfer transistor 216-1, and transfer gate TX2 of transfer transistor 216-2 may be a planar gate electrode and/or further include a vertical gate extending from the corresponding planar gate into the semiconductor material layer 213 proximate to the respective photosensor 214-1, 241-2.

Referring next to FIG. 5C that illustrates a cross-section of the pixel arrangement 202 along the plane C-C of FIG. 4, the first pixel's photosensor 214-1 and the second pixel's photosensor 214-2 are shown disposed and/or embedded in the semiconductor material layer 213. The first pixel's OFG transistor 218-1, the first pixel's transfer transistor 216-1, the DFD transistor 224a, the second pixel's transfer transistor 216-2, and the second pixel's OFG transistor 218-2 can be at least partially disposed on the semiconductor material layer 213. As shown in FIG. 4, the third cross-sectional plane C-C extends in multiple directions, so the components illustrated herein may not lie on a same, two-dimensional physical plane. As shown, the OFG transistor 218 and the transfer transistor 216 of each pixel 204 can be disposed on opposite ends of the corresponding photosensor 214. Accordingly, as discussed in further detail below with reference to FIG. 6, image charge generated by each photosensor 214 can flow to either the OFG transistor 218 or the transfer transistor 216.

Furthermore, the first isolation region 215-1 can be disposed on a side of the OFG transistor 218-1 opposite the transfer transistor 216-1, and can isolate the illustrated pixel arrangement 202 from an adjacent pixel arrangement (not shown). The second isolation region 215-2 can be disposed underneath the DFD transistor 224a, and can isolate the transfer transistor 216-1 from the transfer transistor 216-2. The third isolation region 215-3 can be disposed on a side of the OFG transistor 218-2 opposite the transfer transistor 216-2, and can isolate the illustrated pixel arrangement 202 from an adjacent pixel arrangement (not shown).

Referring next to FIG. 5D that illustrates a cross-section of the pixel arrangement 202 along the plane D-D of FIG. 4, the first pixel's OFG transistor 218-1, the first pixel's LFG transistor 222-1, the DFD transistor 224a, the second pixel's LFG transistor 222-2, and the second pixel's OFG transistor 218-2 can be at least partially disposed on the semiconductor material layer 213 (e.g., in a generally linear arrangement). Also, (i) a first S/D region can be disposed or embedded in the semiconductor material layer 213 between and/or shared by the OFG transistor 218-1 and the LFG transistor 222-1, (ii) a second S/D region can be disposed or embedded in the semiconductor material layer 213 between and/or shared by the LFG transistor 222-1 and the DFD transistor 224a, (iii) a third S/D region can be disposed or embedded in the semiconductor material layer 213 between and/or shared by the DFD transistor 224a and the LFG transistor 222-2, and/or (iv) a fourth S/D region can be disposed or embedded in the semiconductor material layer 213 between and/or shared by the LFG transistor 222-2 and the OFG transistor 218-2. As shown, the first pixel's LOFIC 220-1 and MOM capacitor 223-1 can be coupled to the first and second S/D regions, respectively, and the second pixel's MOM capacitor 223-2 and LOFIC 220-2 can be coupled to the third and fourth S/D regions, respectively.

Furthermore, a fourth isolation region 215-4 can be disposed on a side of the OFG transistor 218-1 opposite the LFG transistor 222-1, and a fifth isolation region 215-5 can be disposed on a side of the OFG transistor 218-2 opposite the LFG transistor 222-2. Each of the first and second isolation regions 215 can isolate the illustrated pixel arrangement 202 from an adjacent pixel arrangement (not shown). The fourth and fifth isolation regions 215 illustrated in FIG. 5D can be the same as or separate from the first, second, and/or third isolation regions 215 illustrated in FIGS. 5A, 5B, and 5C.

FIG. 6 is a partially schematic diagram illustrating various image charge transfer paths along the pixel arrangement 202 in accordance with various embodiments of the present technology. Specifically, the solid arrows, each extending either (a) from a corresponding one of the photosensors 214 to the TCG transistor 230 or (b) from the TCG transistor 230 to the FD 228, can represent image charge transfer paths (“signal readout paths”) for signal readout, for example of high conversion gain. In addition, the dashed arrows, each extending from one of the photosensors 214 to a corresponding one of the source/drain (S/D) regions positioned between a corresponding one of the OFG transistors 218 and a corresponding one of the LFG transistors 222, can represent image charge transfer paths (“overflow paths”) for image charge photogenerated by the photosensor 214. Furthermore, dashed arrows, each extending from a corresponding one of the source/drain (S/D) regions positioned between a corresponding one of the OFG transistors 218 and a corresponding one of the LFG transistors 222 to the TCG transistor 230, can represent signal readout paths, for example of low or LOFIC conversion gain. In addition, a bolded dashed arrow extending from the TCG transistor 230 to the RST transistor 226 can represent a charge draining path (“anti-blooming path”).

Referring first to the overflow paths, excess image charge photogenerated by the photosensors 214 (e.g., during an exposure/integration period and/or while the corresponding transfer transistors 216 are deactivated) can travel and/or overflow along the overflow paths across the corresponding OFG transistors 218 to the corresponding S/D regions (e.g., for storage on corresponding LOFICs and/or MOM capacitors of the pixels). Referring now to the anti-blooming paths, excess image charge at the S/D regions can (e.g., during the exposure/integration period/readout operation) travel and/or overflow across the corresponding LFG transistors along the anti-blooming paths drained to the pixel voltage PixVDD. In some embodiments, the DFD transistors 224, the TCG transistor 230, and the RST transistor 226 can be activated (e.g., during the exposure/integration period and/or while the OG transistor 232 is deactivated) such that image charge that travels and/or overflows across an LFG transistor 222 along anti-blooming paths can be cleared out of the pixel arrangement 202 via the corresponding DFD transistor 224, the TCG transistor 230, and the RST transistor 226. For example, excess image charge photogenerated by one of the photosensors 214 while the corresponding transfer transistor 216 is deactivated can overflow across the corresponding OFG transistor 218 and the corresponding LFG transistor 222 (both deactivated), and be cleared out of the pixel arrangement 202 via one of the DFD transistors 224, the TCG transistor 230, and the RST transistor 226 (all activated).

As illustrated in FIG. 6, the anti-blooming path and the signal readout path both pass through the TCG transistor 230, but proceed in opposite directions therefrom. Advantageously, separating the anti-blooming and signal readout paths can help ensure that signal readouts during the readout period are unaffected by the excess image charge that traveled through the pixel arrangement 202 during the exposure/integration period. This can help improve the overall image quality while still providing anti-blooming functionality.

Referring next to the signal readout paths shown in solid lines, during a readout period following the exposure/integration period, image charge photogenerated by the photosensors 214 can be transferred to the FD 228 via the corresponding transfer transistors 216, the TCG transistor 230, and the OG transistor 232. As one of ordinary skill in the art will appreciate, the four transfer transistors 216 can be controlled (e.g., via corresponding control signals TX1-TX4) to transfer image charge from the four photosensors 214 simultaneously or in a staggered manner to provide binned readout, non-binned readout, etc. For example, image charge can be read out of each pixel independently of image charge of the other pixels. Alternatively, image charge from two or more pixels (e.g., two pixels, three pixels, four pixels) can be readout from the two or more pixels simultaneously such that the image charge from the two or more pixels is binned and readout from the pixel arrangement 202 together. Each of the TCG transistor 230 and the OG transistor 232 can be controlled (e.g., via corresponding control signals) to transfer image charge to the FD 228 and provide various conversion gain levels. Example control timings of the various transistors included in the pixel arrangement 202 are discussed in further detail in cofiled, copending, and coassigned U.S. patent application Ser. No. 18/979,432, filed Dec. 12, 2024, and titled “IMAGE SENSORS WITH PIXEL ARRANGEMENTS HAVING MULTI-GATE TRANSFER STRUCTURES,” which is incorporated herein by reference in its entirety.

In some embodiments, image charge stored on one of more LOFICs 220 and/or one or more MOM capacitors 223 of the pixels 204 can be readout (e.g., during a photosensor readout period and/or during a LOFIC readout period). For example, excess image charge photogenerated by a photosensor 214 of a pixel 204 (e.g., during the exposure/integration period) that (i) travels and/or overflows along the corresponding overflow path across the corresponding OFG transistor 218 to the corresponding LOFIC 220 and/or (ii) travels and/or overflows along the corresponding anti-blooming path across the corresponding LFG transistor 222 to the corresponding MOM capacitor 223, can be read out of the pixel arrangement 202 at for different conversion gains along the signal readout path extending from the TCG transistor 230 to the FD 228. Readout of the image charge from the LOFIC 220 and/or the MOM capacitor 223 can be accomplished by, while the RST transistor 226 is deactivated, activating the corresponding LFG transistor 222, the corresponding DFD transistor 224a or 224b, the TCG transistor 230, and/or the OG transistor 232. In at least some of these embodiments, the transfer transistor 216 of the corresponding pixel 204 and/or of one or more of the other pixels 204 can be deactivated.

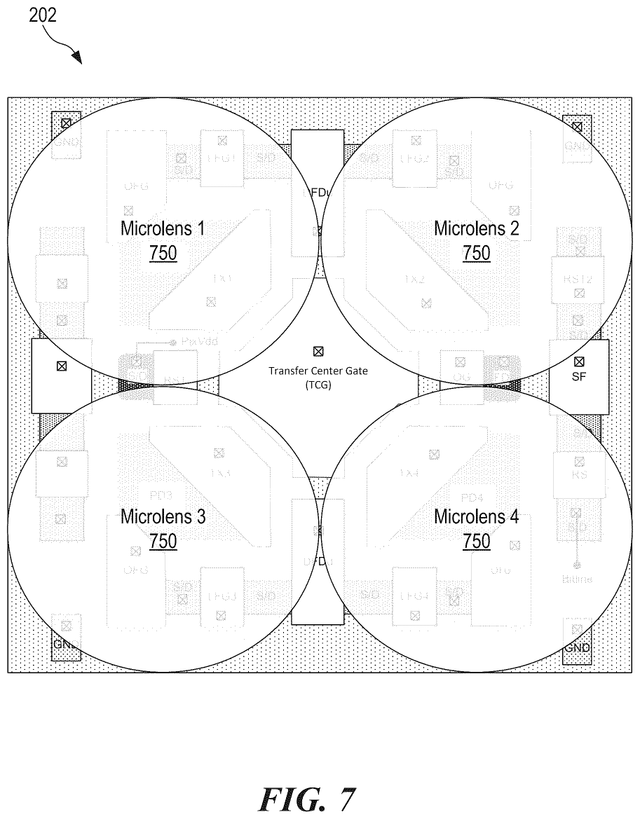

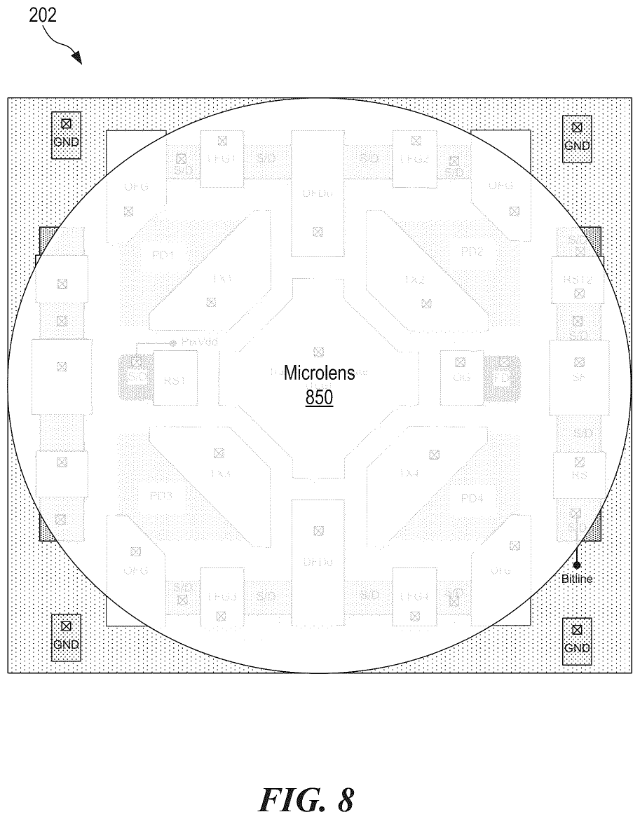

FIG. 7 is a partially schematic diagram illustrating a plurality of microlenses 750 disposed over the pixel arrangement 202 in accordance with various embodiments of the present technology. In the illustrated embodiment, four circular microlenses 750 are disposed over non-overlapping quadrants of the pixel arrangement 202 such that each microlens 750 is sized and positioned to cover a corresponding one of the pixels 204. FIG. 8 is a partially schematic diagram illustrating a single microlens 850 disposed over the pixel arrangement 202 in accordance with various embodiments of the present technology. In the illustrated embodiment, the single microlens 850 is circular and is generally centered with the pixel arrangement 202 such that the microlens 850 is sized and positioned to cover the four pixels 204.

Referring to FIGS. 7 and 8 together, the microlenses 750 and 850 can focus incoming light and thereby increase the total amount of light that reaches the photosensors 214. Therefore, the microlens 750 and 850 can improve the sensitivity of the pixels 204 and the overall image quality, which can be particularly beneficial in low-light conditions. The microlenses 750 and 850 can also reduce optical crosstalk between adjacent pixels 204, which can cause blurring. Furthermore, the microlenses 750 and 850 can enable the use of smaller pixels without sacrificing performance.

Although discussed and illustrated in FIGS. 2-8 with four pixels 204 arranged in a 2×2 configuration, the present technology is not so limited. Pixel arrangements configured in accordance with other embodiments of the present technology can include any other number of pixels (e.g., one pixel, two pixels, three pixels, or more than four pixels). Additionally, or alternatively, pixels included in pixel arrangements configured in accordance with other embodiments of the present technology can be arranged in other configurations besides 2×2. For example, pixels of other pixels arrangements configured in accordance with the present technology can include pixels arranged in a 1×1 configuration, 1×2 configuration, a 2×1 configuration, a 1×3 configuration, a 3×1 configuration, a 1×4 configuration, a 4×1 configuration, etc.

### C. Conclusion

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology as those skilled in the relevant art will recognize. For example, although steps are presented in a given order above, alternative embodiments may perform steps in a different order. Furthermore, the various embodiments described herein may also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where context permits, singular or plural terms may also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, an exemplary step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.” Also, the terms “connect” and “couple” are used interchangeably herein and refer to both direct and indirect connections or couplings. For example, where the context permits, element A “connected” or “coupled” to element B can refer (i) to A directly “connected” or directly “coupled” to B and/or (ii) to A indirectly “connected” or indirectly “coupled” to B.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A pixel arrangement, comprising:
a transfer center gate (TCG) transistor disposed at least partially on a semiconductor material layer;
a plurality of pixels arranged to surround the TCG transistor, each of the plurality of pixels including:
a photosensor disposed in the semiconductor material layer, and
a transfer transistor having a transfer gate disposed at least partially on the semiconductor material layer between the photosensor and the TCG transistor; and
a floating diffusion disposed in the semiconductor material layer between two of the plurality of pixels.

2. The pixel arrangement of claim 1, further comprising a source follower transistor disposed at least partially on the semiconductor material layer at a location proximate the floating diffusion, wherein the floating diffusion is coupled to the source follower transistor via a metal interconnect having a length corresponding to a minimum design rule.

3. The pixel arrangement of claim 1, wherein the plurality of pixels includes four pixels arranged in a 2×2 array, and wherein the TCG transistor is disposed at a center of the 2×2 array.

4. The pixel arrangement of claim 1, wherein the pixel arrangement lacks a junction disposed in the semiconductor material layer that is electrically positioned between (a) the TCG transistor and (b) one or more of the transfer transistors.

5. The pixel arrangement of claim 1, further comprising an outgoing gate (OG) transistor disposed at least partially on the semiconductor material layer between the two of the plurality of pixels and proximate the floating diffusion, wherein the OG transistor is electrically positioned between the TCG transistor and the floating diffusion.

6. The pixel arrangement of claim 5, wherein the pixel arrangement lacks a junction disposed in the semiconductor material layer that is electrically positioned between (a) the TCG transistor and (b) the OG transistor.

7. The pixel arrangement of claim 1, wherein each of the plurality of pixels further includes:
a lateral overflow integration capacitor (LOFIC) coupled to the photosensor for receiving image charge overflow from the photosensor; and
an overflow gate (OFG) transistor disposed at least partially on the semiconductor material layer and positioned between the photosensor and the LOFIC to selectively couple the photosensor to the LOFIC.

8. The pixel arrangement of claim 7, wherein the plurality of pixels includes four pixels arranged in a 2×2 array, each of the four pixels further including a lateral flow gate (LFG) transistor disposed at least partially on the semiconductor material layer at a periphery of the 2×2 array, and wherein the pixel arrangement further comprises:
a first dual floating diffusion (DFD) transistor disposed at least partially on the semiconductor material layer and electrically positioned between the LFG transistors associated with first and second ones of the pixels, wherein the LFG transistors associated with the first and second ones of the pixels are aligned in a horizontal direction; and
a second DFD transistor disposed at least partially on the semiconductor material layer and electrically positioned between the LFG transistors associated with third and fourth ones of the pixels, wherein the LFG transistors associated with the third and fourth ones of the pixels are aligned in a horizontal direction.

9. The pixel arrangement of claim 8, wherein the first DFD transistor is disposed at least partially between the transfer gates of the transfer transistors of the first and second ones of the pixels, and wherein the second DFD transistor is disposed at least partially between the transfer gates of the transfer transistors of the third and fourth ones of the pixels.

10. The pixel arrangement of claim 8, wherein the TCG transistor is coupled to each of the first DFD transistor, the second DFD transistor, and the transfer gates of the transfer transistors of the four pixels without a junction.

11. The pixel arrangement of claim 8, wherein each of the four pixels further includes a metal-oxide-metal (MOM) capacitor coupled to a source/drain region that is electrically positioned between (a) the LFG transistor and (b) either the first DFD transistor or the second DFD transistor.

12. The pixel arrangement of claim 8, wherein the pixel arrangement lacks (i) a junction disposed in the semiconductor material layer that is electrically positioned between the first DFD transistor and the TCG transistor and/or (ii) a junction disposed in the semiconductor material layer that is electrically positioned between the second DFD transistor and the TCG transistor.

13. The pixel arrangement of claim 1, wherein the TCG transistor has a gate area larger than a gate area of each of the transfer transistors.

14. The pixel arrangement of claim 1, wherein the plurality of pixels includes four pixels, and wherein the four pixels and the TCG transistor are symmetrical about at least two symmetry lines.

15. The pixel arrangement of claim 1, further comprising a reset transistor disposed at least partially on the semiconductor material layer in a manner such that the floating diffusion and the reset transistor are positioned on opposite sides of the TCG transistor.

16. The pixel arrangement of claim 15, wherein the pixel arrangement lacks a junction disposed in the semiconductor material layer that is electrically positioned between (a) the TCG transistor and (b) the reset transistor.

17. A pixel arrangement, comprising:
a transfer center gate (TCG) transistor disposed at least partially on a semiconductor material layer;
a plurality of pixels arranged about a periphery of the TCG transistor, each pixel of the plurality of pixels including:
a photosensor disposed in the semiconductor material layer, and
a transfer transistor disposed at least partially on the semiconductor material layer and positioned between the photosensor and the TCG transistor;
a source follower transistor; and
a floating diffusion disposed in the semiconductor material layer and selectively coupled to the photosensors by a transfer center gate of the TCG transistor, wherein the floating diffusion is further coupled to a gate electrode of the source follower transistor.

18. The pixel arrangement of claim 17, wherein the TCG transistor comprises a MOSCAP configured to hold image charge photogenerated by the photosensors of the plurality of pixels.

19. The pixel arrangement of claim 17, wherein the TCG transistor is coupled to one or more of the transfer transistors without an intervening junction disposed in the semiconductor material layer.

20. The pixel arrangement of claim 17, further comprising an overflow gate (OG) transistor disposed at least partially on the semiconductor material layer at a location between the TCG transistor and the floating diffusion.

21. The pixel arrangement of claim 20, wherein the TCG transistor is coupled to the OG transistor without an intervening junction disposed in the semiconductor material layer.

22. The pixel arrangement of claim 17, further comprising:
a reset transistor disposed at least partially on the semiconductor material layer such that the TCG transistor is positioned between the reset transistor and the floating diffusion,
wherein a first distance between the floating diffusion and the gate electrode of the source follower transistor is smaller than a second distance between the floating diffusion and a gate electrode of the reset transistor.

23. The pixel arrangement of claim 22, wherein the TCG transistor is coupled to the reset transistor without an intervening junction disposed in the semiconductor material layer.
